(19) United States
(12) Patent Application Publication
(10) Pub. No.: US 2022/0316966 A1
(43) Pub. Date: Oct. 6, 2022

(54) ANTI-PINCH SENSOR WITH QUICK CONNECT FEATURE AND METHOD OF CONNECTING SAME TO A WIRING HARNESS

(71) Applicant: Magna Closures Inc., Newmarket (CA)

(72) Inventors: Thomas MELLARY, Newmarket (CA); Mihai TRAMBITAS, Newmarket (CA)

(21) Appl. No.: 17/616,700

(22) PCT Filed: Jun. 3, 2020
(86) PCT No.: PCT/CA2020/050767

§ 371 Date: Dec. 6, 2021

Related U.S. Application Data
(60) Provisional application No. 62/863,749, filed on Jun. 19, 2019.

(51) Int. Cl. G01L 1/22

(52) U.S. Cl. CPC G01L 1/2287; E05F 15/44

(57) ABSTRACT

A contact sensor and method of construction thereof are provided. The contact sensor has a sensor body extending along an axis between a first end and an opposite second end. The sensor body has an internal cavity extending from the first end to the second. A first conductor extends through the internal cavity between the first end and the second end. A second conductor extends through the internal cavity, in spaced relation from the first conductor, between the first end and the second end. A wire harness is fixed in electrical communication with the first conductor and the second conductor adjacent at least one of the first end and the second end of the sensor body. The first conductor and the second conductor do not extend axially outwardly from the internal cavity beyond the first end and the second end of the sensor body.

### CROSS-REFERENCE TO RELATED APPLICATION

This application claims the benefit of U.S. Provisional Application Ser. No. 62/863,749, filed Jun. 19, 2019, which is incorporated herein by reference in its entirety.

### FIELD

The present disclosure relates generally to sensors, and more particularly to pressure and pinch sensors for vehicles, such as for vehicle seats, windows and closure panels where it is desirable to detect the presence of a person or some other object.

### BACKGROUND

This section provides background information related to the present disclosure which is not necessarily prior art.

It is known to apply pinch sensors to prevent a power-activated window or closure panel, such as a lift gate or side door, from closing if a foreign obstacle or object is detected as the panel is closing. It is further known to apply a switch to an automotive seat to detect the presence of a passenger, which in turn can activate or deactivate an inflationary restraint apparatus, often referred to as airbag. The pinch sensors and switches come in different forms, including non-contact sensors, such as those based on capacitance changes, and contact sensors that rely on a physical deformation of the sensor caused by contact with a foreign object.

The contact pinch sensors are typically applied in the form of a sensor body strip extending between opposite ends. The sensor body strip typically includes a rubber strip configured to be routed along and adjacent to a periphery of the application, such as a vehicle door. The rubber strip is conductive and embeds two small diameter conductive wires which are typically spaced from one another, often by an air gap. A resistor is typically fixed in electrical communication to first ends of the two conductive wires adjacent a first free end of the sensor body strip and a wire harness is typically fixed in electrical communication to second ends, opposite the first ends, of the two conductive wires adjacent a second connector end, opposite the first free end, of the sensor body strip. When the two conductive wires are caused to contact one another under an impact force applied directly onto an outer, nonconductive sheath of the sensor body strip, typically a non-conductive elastomeric material, wherein the outer sheath encases the inner conductive rubber strip and the two conductive wires, the electrical resistance between the conductive wires drops, and a microcontroller, operably connected to a connector of the wire harness, detects the drop in resistance or voltage, thereby detecting an object when the resistance or voltage drop exceeds a predetermined threshold.

Although the contact pinch sensors described above are generally useful to perform their intended function, some issues result due to their structure, including the structural mechanisms of interconnections between various components thereof, as well as to their method of construction and numerous steps involved therewith. For example, difficulties are typically encountered during attachment of the resistor to the first ends of the two conductive wires as well as during attachment of the wire harness to the second ends of the two conductive wires. Not only is it generally difficult to make secure and reliable electrical connections, but it is generally time consuming and costly. Some of the aforementioned challenges come from having to first strip a portion of the outer, nonconductive sheath along with the conductive rubber strip to expose a desired length of the two conducive wires at each of the first and second ends of the sensor body strip, such that the exposed desired length of the wires extend axially outwardly from the outer, nonconductive sheath. It is important to expose the desired length fairly precisely without damaging the conductive wires, otherwise the ability to make a secure reliable connection to the exposed length of the wires can be compromised. Further processes and challenges occur by then having to crimp the exposed lengths of the two conductive wires to wires extending from the resistor as well as to wires of the wire harness, particularly if the length of the exposed wires is other than desired. If any of the numerous steps are not performed properly, the entirety of the components, particularly the sensor body strip, can be relegated as scrap.

It is therefore desired to provide a contact pinch sensor/switch and method of construction thereof that obviates or mitigates at least one or more of the above-identified disadvantages.

### SUMMARY

This section provides a general summary of the disclosure and is not intended to be a comprehensive listing of all features, advantages, aspects and objectives associated with the inventive concepts described and illustrated in the detailed description provided herein.

It is an object of the disclosure to provide a contact sensor that overcomes one or more of the problems associated with known contact sensors.

It is a further object of the disclosure to provide a contact pinch sensor that overcomes one or more of the problems associated with known contact pinch sensors.

It is a further object of the disclosure to provide a method of constructing a contact sensor that overcomes one or more of the problems associated with known methods of constructing contact sensors.

It is a further object of the disclosure to provide a method of constructing a contact pinch sensor that overcomes one or more of the problems associated with known methods of constructing contact pinch sensors.

It is a further object of the disclosure to provide a method of constructing a contact sensor, such as a contact pinch sensor, that reduces the number of process steps in comparison with known methods of constructing contact sensors.

It is a further object of the disclosure to provide a contact sensor, such as a contact pinch sensor, having reliable, durable and long lasting electrical connections between the various components thereof.

In accordance with these and other objects, it is an aspect of the present disclosure to provide a variable resistance contact sensor for use in a powered closure system, including power lift gates, power windows, power sunroofs, power deck-lids, and also in trim panel movement detection, exterior door handle activation pressure detection, non-planar switch applications, including occupant detection on a vehicle seat, for example.

It is a related aspect of the present disclosure to provide a contact sensor that is formable to attain any desired shape as viewed in lateral cross-section taken generally transversely to a longitudinal, lengthwise extending axis of the contact sensor.

It is a related aspect of the present disclosure to provide a sensor body of a contact sensor that is extrudable, thereby reducing the cost associated with manufacture.

It is a related aspect of the present disclosure to provide a sensor body of a contact sensor that is moldable, thereby being able to form intricately shaped sensor bodies, including asymmetrically shaped sensor bodies, in a cost-effective manner.

In accordance with these and other aspects, a variable resistance contact sensor is provided including a sensor body extending along an axis between a first end and an opposite second end. The sensor body has an internal cavity, with a first conductor extending through the internal cavity between the first end and the second end and a second conductor extending through the internal cavity, in spaced relation in its entirety from the first conductor, between the first end and the second end. A wire harness is fixed in electrical communication with the first conductor and the second conductor adjacent one of the first and second ends of the sensor body, wherein the first conductor and the second conductor do not extend axially outwardly from the internal cavity beyond the first end and the second end of the sensor body.

In accordance with another aspect of the disclosure, a resistor can be fixed in electrical communication with the first conductor and the second conductor adjacent one of the first and second ends of the sensor body opposite the wire harness.

In accordance with another aspect of the disclosure, the first conductor and the second conductor can be provided as a first wire and a second wire, respectively.

In accordance with another aspect of the disclosure, the first wire and the second wire can terminate in substantially flush relation with the first end and the second end of the sensor body, thereby facilitating the ease and reducing the cost associated with manufacture.

In accordance with another aspect of the disclosure, a conductive resistor connector portion is fixed in electrical communication with the resistor, with the conductive resistor connector portion being disposed in the internal cavity in electrical communication with the first wire and the second wire.

In accordance with another aspect of the disclosure, the conductive resistor connector portion can extend along the axis in sandwiched relation between the first wire and the second wire.

In accordance with another aspect of the disclosure, the resistor is disposed outwardly from the internal cavity.

In accordance with another aspect of the disclosure, a conductive wire harness connector portion is fixed in electrical communication with the wire harness, with the conductive wire harness connector portion being disposed in the internal cavity in electrical communication with the first wire and the second wire.

In accordance with another aspect of the disclosure, the conductive wire harness connector portion can extend along the axis in sandwiched relation between the first wire and the second wire.

In accordance with another aspect of the disclosure, the first wire and the second wire are maintained out of direct physical contact with one another in their entirety.

In accordance with another aspect of the disclosure, a first conductive material layer can encapsulate the first wire and a second conductive material layer can encapsulate the second wire, with the first conductive material layer and the second conductive material layer being maintained out of direct physical contact with one another in their entirety.

In accordance with another aspect of the disclosure, the conductive resistor connector portion is in direct electrical contact with the first conductive material layer and the second conductive material layer.

In accordance with another aspect of the disclosure, the conductive resistor connector portion can extend along the axis in sandwiched relation between the first conductive material layer and the second conductive material layer.

In accordance with another aspect of the disclosure, the conductive wire harness connector portion is in direct electrical contact with the first conductive material layer and the second conductive material layer.

In accordance with another aspect of the disclosure, the conductive wire harness connector portion can extend along the axis in sandwiched relation between the first conductive material layer and the second conductive material layer.

In accordance with another aspect of the disclosure, the resistor can be operably coupled in series with the sensor body.

In accordance with another aspect of the disclosure, a voltage controlled pulse width modulator (PWM) can be disposed in operably coupled relation with the sensor body and the resistor.

In accordance with another aspect of the disclosure, the sensor body can exhibit an increase in electrical resistance in response to being elastically deformed when acted upon by an applied force resulting from the external contact.

In accordance with another aspect of the disclosure, the sensor body can exhibit an increase in electrical resistance in response to an increase in temperature resulting from the external contact.

In accordance with another aspect of the disclosure, a backing member can be attached along a portion of the sensor body between the first end and the second end, wherein the backing member can facilitate attaching the sensor body to a vehicle component.

In accordance with another aspect of the disclosure, the sensor body can be provided having a constant, non-varying profile, as viewed in lateral cross-section taken generally transversely to the axis, along its entire length extending between the first end and the second end.

In accordance with another aspect of the disclosure, the sensor body can be provided having a varying profile along its length, as viewed in lateral cross-section taken generally transversely to the axis at different locations between the first end and the second end.

In accordance with another aspect of the disclosure, a microcontroller can be operably connected in electrical communication with at least one of the first and second wires of the sensor body.

In accordance with another aspect of the disclosure, the microcontroller can be operably connected to the first wire, with the microcontroller being configured to detect the presence of external contact to the sensor body as a result of an increase in electrical resistance in response to the sensor body being elastically deformed.

In accordance with another aspect of the disclosure, the microcontroller can be operably connected to the first wire, with the microcontroller being configured to detect the presence of external contact on the sensor body as a result of an increase in electrical resistance in response to an increase in temperature resulting from the external contact.

In accordance with another aspect of the disclosure, the sensor body can be formed as an elongate strip of material configured as a pinch sensor, such as for a vehicle window.

In accordance with another aspect of the disclosure, the sensor body can be configured to sense pressure and/or temperature change.

In accordance with another aspect of the disclosure, the sensor body can be configured with an ability to be compressed, bent, twisted and/or stretched without causing damage to the sensor body.

In accordance with another aspect of the disclosure, a method of constructing a variable resistance contact sensor is provided. The method includes a providing a sensor body having an internal cavity extending between a first end and an opposite second end, with a first conductor and a second conductor extending through the internal cavity in spaced relation from one another and terminating in substantially flush relation with the first end and the second end. Further, providing a wire harness assembly having a wire harness connector portion and a wire harness including a plurality of wires fixed to the wire harness connector portion. Then, inserting the wire harness connector portion into the internal cavity of the sensor body adjacent one of the first end and the second end and bringing the plurality of wires into electrical communication with the first conductor and the second conductor.

In accordance with a further aspect, the method can further include providing a resistor assembly having a resistor connector portion and a resistor fixed to the resistor connector portion. Then, inserting the resistor connector portion into the internal cavity of the sensor body adjacent one of the first end and second end, opposite the wire harness, and bringing the resistor into electrical communication with the first conductor and the second conductor.

In accordance with a further aspect, the method can include providing the resistor connector portion having resistor conductive regions in electrical communication with the resistor and bringing the resistor conductive regions into electrical communication with the first conductor and the second wire automatically as a result of inserting the resistor connector portion into the internal cavity of the sensor body.

In accordance with a further aspect, the method can include providing the first conductor having a first conductive material layer encapsulating or substantially encapsulating the first conductor and the second conductor having a second conductive material layer encapsulating or substantially encapsulating the second conductor and bringing the resistor conductive regions into direct electrical contact with the first conductive material layer and second conductive material layer automatically upon inserting the resistor connector portion into the internal cavity of the sensor body.

In accordance with a further aspect, the method can include providing the first conductor and the second conductor as a first wire and a second wire, respectively.

In accordance with a further aspect, the method can include providing the wire harness connector portion having wire harness conductive regions in electrical communication with the plurality of wires and bringing the wire harness conductive regions into electrical communication with the first wire and the second wire automatically upon inserting the wire harness connector portion into the internal cavity of the sensor body.

In accordance with a further aspect, the method can include providing the first wire having a first conductive material layer encapsulating the first wire and the second wire having a second conductive material layer encapsulating the second wire and bringing the wire harness conductive regions into direct electrical contact with the first conductive material layer and the second conductive material layer automatically upon inserting the wire harness connector portion into the internal cavity of the sensor body.

These and other aspects are directed, as will be understood by a person possessing ordinary skill in the art upon viewing the disclosure herein, to providing a sensor and/or switch having a variable resistance sensor body for detection of at least one of pressure and thermal change when a component of a motor vehicle is contacted.

Further areas of applicability will become apparent to a person possessing ordinary skill in the art from the description and drawings provided herein. The description, drawings and specific examples in this summary are intended for purposes of illustration only and are not intended to limit the scope of the present disclosure.

### BRIEF DESCRIPTION OF THE DRAWINGS

These and other aspects, features, and advantages of the present disclosure will be readily appreciated, as the same becomes better understood by reference to the following detailed description when considered in connection with the accompanying drawings, wherein:

FIG. 1 is a schematic perspective top view of a contact sensor constructed in accordance with one aspect of the present disclosure;

FIG. 2A is a fragmentary exploded perspective view illustrating a resistor assembly including a resistor and a conductive resistor connector portion, configured in electrical communication with one another, exploded from a first end of a conductor body of the conductor sensor of FIG. 1;

FIG. 2B is a view similar to FIG. 2A illustrating the resistor assembly assembled to the first end of the conductor body;

FIGS. 2C-2D are views similar to FIG. 2B shown partially cross-sectioned;

FIG. 3A is a fragmentary exploded perspective view of a wire harness and a conductive wire harness connector portion of the contact sensor of FIG. 1;

FIG. 3B is an assembled perspective view of the wire harness and conductive wire harness connector portion of FIG. 3A;

FIG. 4A is a fragmentary exploded perspective view illustrating the wire harness and conductive wire harness connector portion, configured in electrical communication with one another, exploded from a second end of a conductor body of the conductor sensor of FIG. 1;

FIG. 4B is a view similar to FIG. 4A illustrating the wire harness and conductive wire harness connector portion assembled to the second end of the conductor body;

FIG. 4C is a view similar to FIG. 4B shown partially cross-sectioned;

FIGS. 5 and 5A are views similar to FIG. 4B illustrating the wire harness and conductive wire harness connector portion covered by a protective end cap;

FIG. 6 is a view similar to FIG. 2B illustrating the resistor assembly covered by a protective end cap;

FIG. 6A is a view similar to FIG. 6 shown partially cross-sectioned;

FIG. 7 is a rear perspective view of the resistor assembly;

FIG. 8 is a partially cross-sectioned rear perspective view of the conductive wire harness connector portion;

FIG. 9 is a schematic cross-sectional side view of a window application including a variable resistance conductive rubber sensor in accordance with one aspect of the teachings of the present disclosure with a window shown in a fully raised position;

FIG. 10 is a view similar to FIG. 9 with the window shown in a lowered position;

FIG. 11 is a view similar to FIG. 9 with an object shown blocking the upward travel of the window and abutting the variable resistance conductive rubber sensor;

FIG. 12 is an electronic schematic diagram of a sensor assembly constructed in accordance with an aspect of the disclosure;

FIG. 13A is a flow process diagram for assembling a contact sensor in accordance with the prior art;

FIG. 13B is a flow process diagram for assembling a contact sensor in accordance with an aspect of the disclosure;

FIG. 14 is a flow diagram illustrating a method of constructing a contact sensor in accordance with another aspect of the disclosure; and

FIG. 15 is a perspective view of a motor vehicle equipped with the contact sensor of FIG. 1, in accordance with an illustrative embodiment.

### DETAILED DESCRIPTION OF EXAMPLE EMBODIMENTS

In general, example embodiments of a contact sensor with quick connect features, such as for example, the type configured to be installed within a power automotive window application, constructed in accordance with the teachings of the present disclosure will now be disclosed. The example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail, as they will be readily understood by the skilled artisan in view of the disclosure herein.

For purposes of descriptive clarity, the present disclosure is described herein in the context of one or more specific vehicular applications, namely powered windows. However, upon reading the following detailed description in conjunction with the appended drawings, it will be clear that the inventive concepts of the present disclosure can be applied to numerous other systems and applications, such as, for example, power lift gates, power roof panels, deck-lids, trim panel movement detection; exterior door handle activation pressure detection; non-planar switch applications, including occupant detection on a vehicle seat, for example.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” “top”, “bottom”, and the like, may be used herein for ease of description to describe one element's or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated degrees or at other orientations) and the spatially relative descriptions used herein interpreted accordingly.

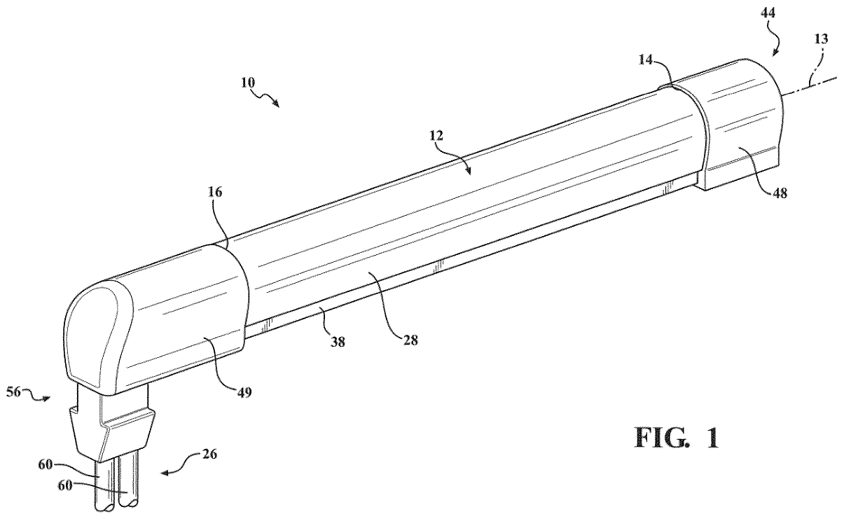

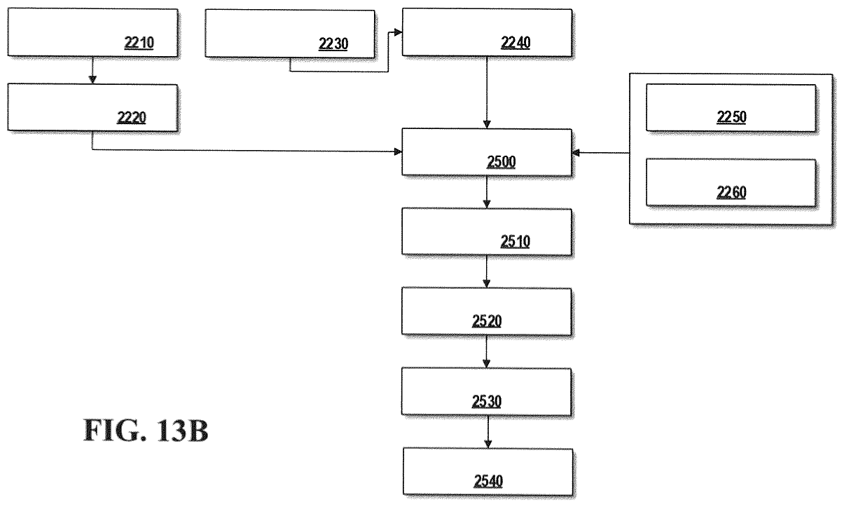

Referring now in more details to the drawings, FIG. 1 illustrates an embodiment of a contact sensor assembly, for example a variable resistance contact sensor assembly, such as may be used as a pinch sensor, by way of example and without limitation, and referred to hereafter simply as contact sensor 10, which is also actively functional as a switch, in accordance with various aspects of the disclosure. The contact sensor 10 has a sensor body 12 constructed at least in part of an elastomeric material. The sensor body 12 is shown, by way of example and without limitation, as extending lengthwise along an axis 13 between a first end 14 and an opposite second end 16. The sensor body 12 is longitudinally flexible relative to the axis 13, twistable in torsion about the axis 13, and radially compressible. The sensor body 12 has an internal cavity 18 with a conductive first wire 20 (also referred to as a first conductor) extending through the cavity 18 between the first end 14 and the second end 16 of the sensor body 12. First wire 20 may be provided as a metal wire, but other configuration are possible, such as an electrically conductive plastic, or polymer, or as an electrically doped region of conductive material layer 30. A second wire 22 (also referred to as a second conductor) extends through the cavity 18, in spaced relation from the first wire 20, between the first end 14 and the second end 16 of the sensor body 12. Second wire 20 may be provided as a metal wire, but other configuration are possible, such as an electrically conductive plastic, or polymer, or as an electrically doped region of second conductive material layer 32. A resistor 24 can be fixed in electrical communication with the first wire 20 and the second wire 22 adjacent one of the first end 14 and the second end 16 of the sensor body 12, and shown as the first end 14, by way of example and without limitation. Resistor 24 may be provided to generate diagnostic signal levels (for example a voltage drop) detectable by the controller for diagnosing the state e.g. plugged-in of the contact sensor 10. A wire harness 26 is fixed in electrical communication with the first wire 20 and the second wire 22 adjacent the other of the first end 14 and the second end 16 of the sensor body 12 opposite the resistor 24, and thus, shown as the second end 16. To facilitate manufacture and assembly, the first wire 14 and the second wire 16 do not extend axially outwardly from the internal cavity 18 beyond the first end 14 and the second end 16 of the sensor body 12. As such, the sensor body 12, with the first and second wires 20, 22 disposed in the cavity 18, can be cut to a desire length, such that the first and second wires 20, 22 are flush or substantially flush with the opposite first and second ends 14, 16 and then assembled to complete assembly of the contact sensor 12 without having to first strip any portion of the sensor body 12 to expose the first and second wires 20, 22. As such, as shown in the process flow diagram of FIG. 13B used to construct contact sensor 10 in accordance with an aspect of the disclosure, numerous process steps used to construct a contact sensor in accordance with the prior art (FIG. 13A) are eliminated, as identified by asterisks in FIG. 13A, thereby making manufacture of contact sensor 10 efficient and low cost relative to the prior art process of FIG. 13A.

With reference to FIG. 13A, process steps used to construct a contact sensor in accordance with the prior art may include the step of stripping the extrusion (resistor end) at step 100, followed by crimping the resistor to the wires at step 200. Prior to step 200, the steps of bending the resistor legs at step 210 followed by the step of molding the resistor plug at step 220 prior to proceed to step 200. Step 200 is followed by stripping the extrusion (harness end) at step 300, then follow by crimping the harness end to the wires at step 400. The process may also include cutting/trimming/crimping the terminals of the wire harness at step 401 followed by the step of assembling the connector to the wire harness at step 420 then proceeding to step 400. The process may also include molding the harness plug at step 430 and molding the harness seal at step 440 before proceeding to step 400. Proceeding step 400 is the step of assembling the wires to the harness plug at step 500, followed by the step of over molding the harness end at step 600, next followed by the step of overmolding the resistor end at step 700 then followed by the EOL test at step 800.

Now referring to FIG. 13B, the steps used to construct contact sensor 10 in accordance with an aspect of the disclosure include the step of providing an assembly plug with a resist added thereto which may be pre-purchased at step 2230, followed next be the step of inserting the plug into the extrusion at step 2240, then next followed by the step of assembling the wires to the harness plug at step 2250. The process may also include the step of cutting/trimming/crimping the wire harness terminals at step 2210, then next assembling the connector to the wire harness at step 2220, then next proceeding to step 2500. The process may also include the step of providing a harness plug, such as a pre-purchased/assemble harness plug at step 2250, then next modling the harness seal at step 2260, then proceeding to step 2500. The process further includes the steps of inserting the plug into the extrusion at step 2510, the next overmolding the harness end at step 2520, the next overmolding the resistor end at step 2530, then next the EOL test at step 2540.

The teachings herein may also be applied to other types of contact sensor assemblies, such as described in U.S. Pat. No. 9,417,099, entitled “Wide Activation angle Pinch Sensor”. Contact sensor 10 may also be configured in a capacitive mode having an upper electrode (optionally comprising a conductor embedded in conductive resin) which acts as a capacitive sensor electrode, and a lower electrode (optionally comprising a conductor embedded in conductive resin) which acts as a capacitive shield electrode. A dielectric (for example a portion of a casing or the body) may be disposed between the upper electrode and the lower electrode to isolate and maintain the distance between the two electrodes. The controller (or sensor processor (“ECU”)) is in electrical communication with the electrodes for processing sensed signals received therefrom.

According to an aspect, the inner cavity 18 of sensor body 12 may be bounded by a circumferentially continuous wall 28 of sensor body 12. Otherwise, the wall 28 of sensor body 12 may have a slit (not shown) extending axially between the first end 14 to the second end 16, thereby allowing the first and second wires 20, 22 to be readily disposed into cavity 18 through the slit, as will be readily understood by one possessing ordinary skill in the art. Further, it is to be recognized that the sensor body 12 can be formed having any desired shape, as viewed in lateral cross-section, such as round, oval, U-shaped, or otherwise.

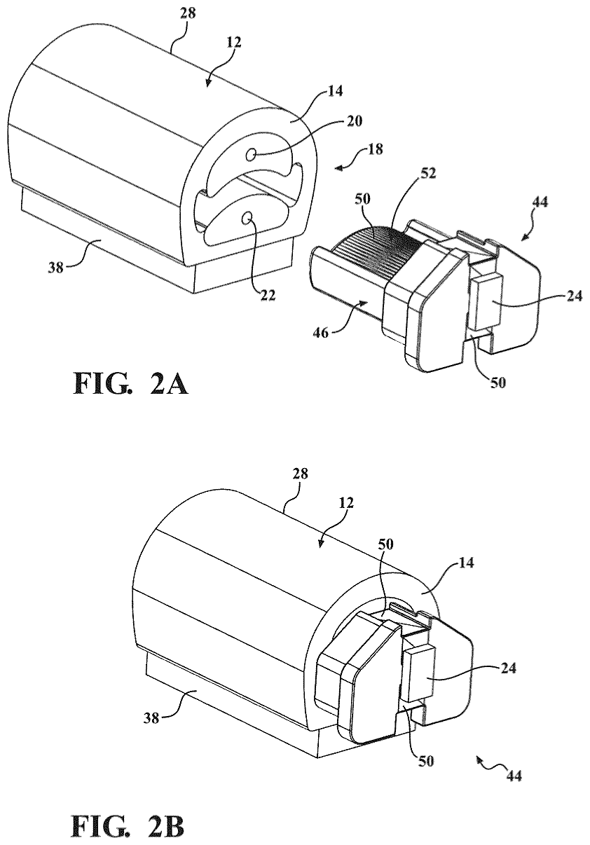

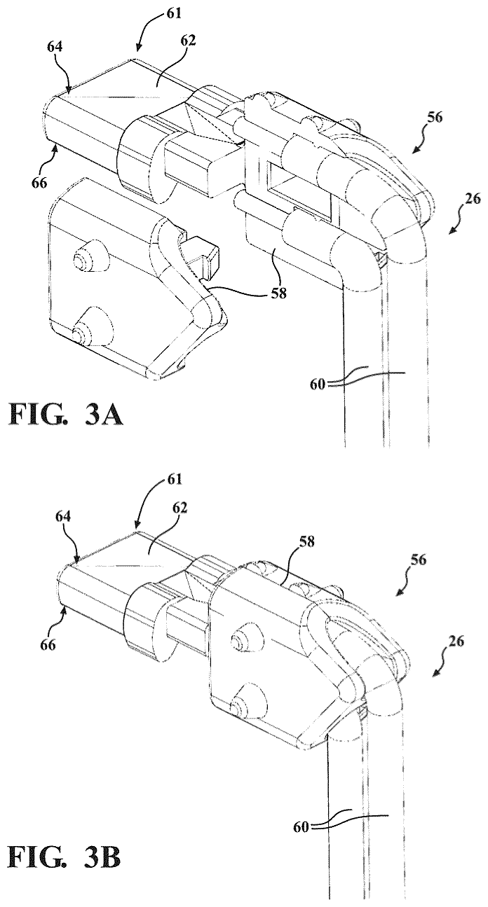

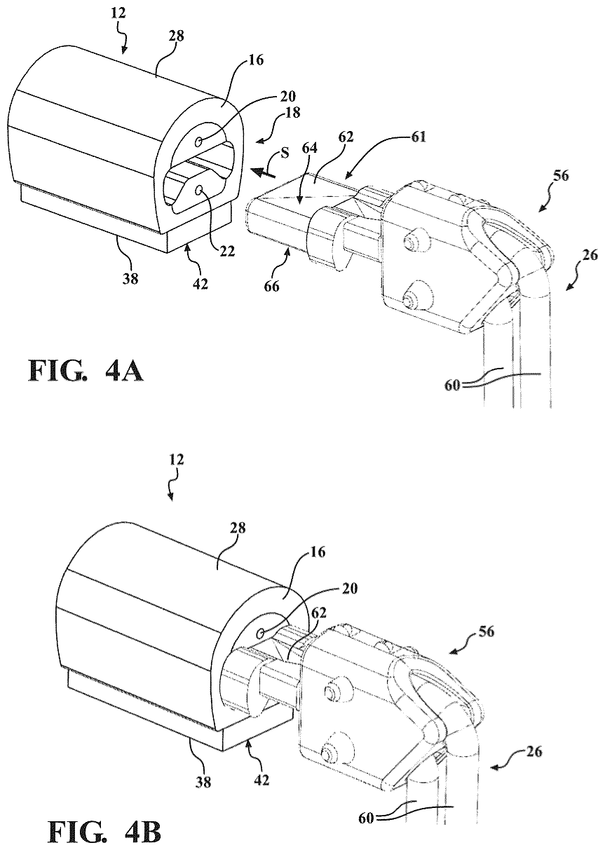

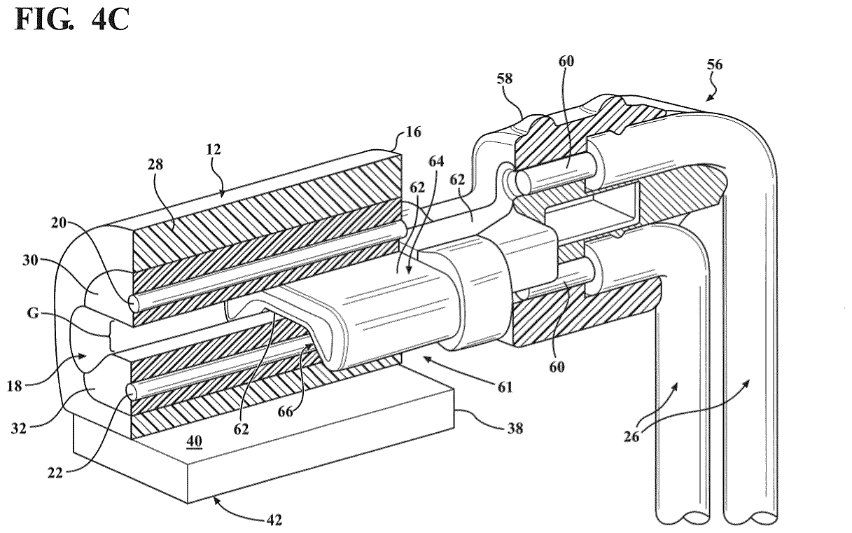

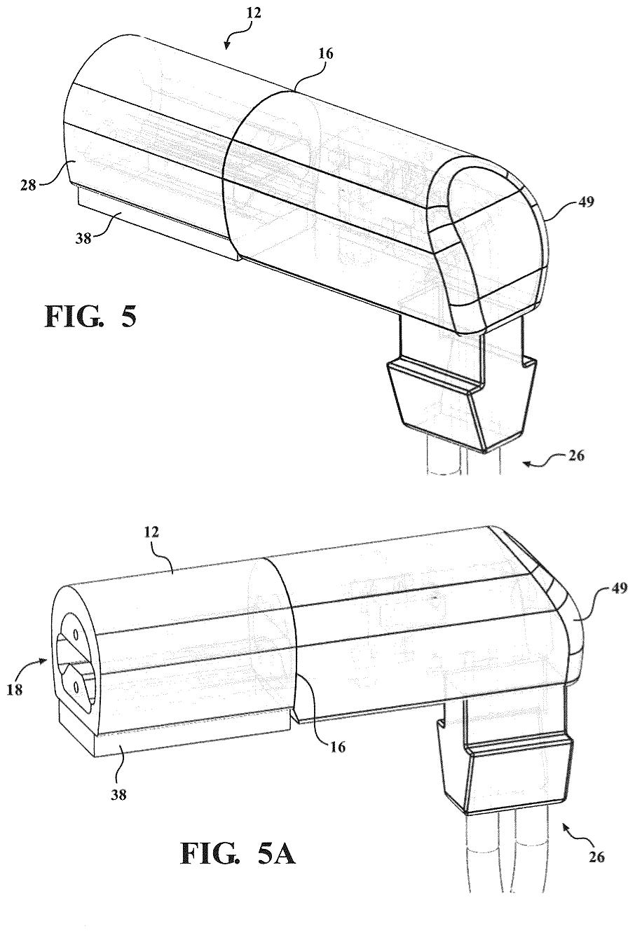

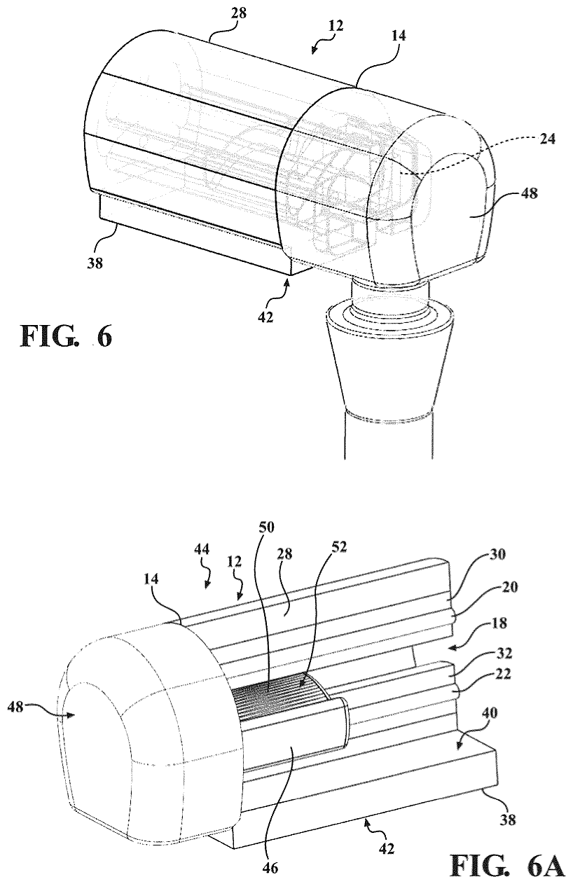

A first conductive material layer 30 can be provided to circumferentially surround and encapsulate the first wire 20 and a second conductive material layer 32 can be provided to circumferentially surround and encapsulate the second wire 22. The first conductive material layer 30 and the second conductive material layer 32 are maintained out of direct physical and electrical contact with one another via a gap G (best seen and identified in FIGS. 2C and 4C) extending along the length of sensor body 12 between the opposite ends 14, 16.

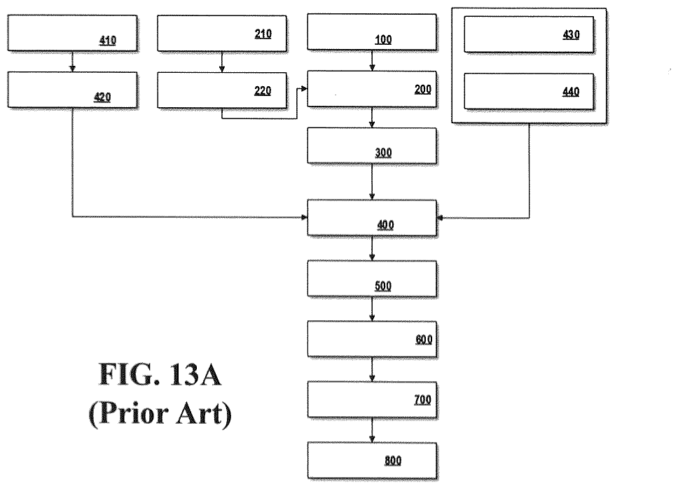

The sensor body 12, when acted upon by an applied force resulting from an external contact, is elastically deformed, such as by being compressed, twisted or stretched, and as a result, the conductive material layers 30, 32 of the sensor body 12 exhibit an increase in electrical resistance. Such an external contact may result from contact with an object or a human body. As such, as shown in FIG. 12, with a voltage being applied across the sensor body 12 via the first and second wires 20, 22, changes in voltage can be detected via a microcontroller 34, which may be configured to execute a desired and selected task, such as via an actuator 36. The microcontroller 34 may, for example, use a software algorithm to detect a change in voltage across the sensor body 12 to detect the external contact with the sensor body 12.

The first and second conductive material layers 30, 32, can be formed from any suitable elastic conductive material, and in accordance with one presently preferred aspect, can be formed from carbon-black silicone rubber, by way of example and without limitation. One such carbon-black silicone rubber material tested had a hardness of 45+/−5 on the Shore A scale; a specific gravity (g/cc) of 1.16+/−0.10; a carbon-black content of about 15%+/−5%; a tensile strength (N/mm2) of about 3.0 MPa+/−0.5 MPa; and an elongation at break (%) between about 150-300. Further, as discussed above, the sensor body 12 can be formed to take on any desired configuration, such as via a molding or extrusion process. Accordingly, the sensor body 12 can be configured to conform to a wide variety of applications requiring a pressure sensor/switch. By virtue of being molded or extruded, the complexity of forming the sensor body 12 is minimized, and thus, so too is the cost associated with its manufacture. Being molded or extruded allows great flexibility as to the formable geometry of the sensor body 12, wherein the sensor body 12 can be formed having a uniform, constant profile along its length, or it can be formed having a varying profile along its length, including varying widths and/or thicknesses, whether stepped or continuously varying. Accordingly, depending on the application, the sensor body 12 can be formed having virtually any desired shape/geometry to fit within the envelope available in the intended application. In addition to the sensor body 12 being useful to detect applied forces as a result of being physically acted upon, i.e. compressed, stretched, twisted, the sensor body 12 material is also able to detect human touch as a result of localized or global change in temperature of the material. Of course, to avoid unwanted activation signals being triggered by the microcontroller 34, the microcontroller 34 can be programmed to account for any anticipated environmental conditions, such expected thermal conditions, by way of example and without limitation.

To facilitate attaching the contact sensor 10 to a mating vehicle component in assembly, a backing member 38 can be attached along a segment of the sensor body 12 between the opposite ends 14, 16, or along the entire length of the sensor body 12. The backing member 38 can be attached to the sensor body 12 along one or more of its sides 40 via any suitable bonding means, including an adhesive glue, pressure-sensitive adhesive, melting, welding, or other suitable method, and can be attached to the mating vehicle component in like fashion along an opposite, outwardly facing side 42. Accordingly, it should be recognized that a double-sided self-adhesive strip or tape could be used for the backing member 38.

The resistor 24 can be provided as part of a self-contained resistor assembly 44, including a quick connect conductive resistor connector portion, referred to hereafter as resistor connector portion 46, fixed in electrical communication with the resistor 24. The resistor connector portion 46 is configured to be readily disposed and fixed in the internal cavity 18 in operable electrical communication with the first wire 20 and the second wire 22. The resistor connector portion 46 extends along the axis 13 in sandwiched relation between the first wire 20 and the second wire 22 in electrical communication therewith. In the example embodiment illustrated, the resistor connector portion 46 is in direct electrical contact with the first conductive material layer 30 and the second conductive material layer 32, such that the resistor connector portion 46 extends along the axis 13 in sandwiched relation between the first conductive material layer 30 and the second conductive material layer 32. As shown, the resistor connector portion 46 is simply inserted axially within the gap G in plug-like fashion to bring the resistor 24 into electrical communication with the first and second wires 20, 22, thereby establishing an easy and reliable electrical connection between the first and second wires 20, 22 and the resistor 24 without having to strip away material of the surrounding wall 28 of the sensor body 12. Then, to secure fixation of the resistor assembly 44 to the sensor body 12, an end cap 48 can be disposed over the resistor assembly 44, with the end cap 48 functioning to both secure attachment of the resistor assembly 44 to the sensor body 12 and to protect the resistor assembly 44 against exposure to contamination from the outside environment and other forms of damage. The end cap 48 can be formed of any suitable polymeric, dielectric material, such as in an over-molding operation, by way of example and without limitation. The end cap 48 may have a low profile shape, conforming substantially to the outer shape of the resistor assembly 44. Otherwise, the end cap 48 could be pre-formed and secured about the resistor assembly 44 and to the end 14 of the sensor body 12 via any suitable adhesive, press-fit, fastener, or otherwise.

The resistor connector portion 46, in order to provide electrical communication between the first and second wires 20, 22 and the resistor 24, has resistor conductive regions, referred to hereafter as conductive regions 50, such as conductive metal strips or conductive layers of material, by way of example and without limitation, extending along respective opposite upper and lower outer surfaces 52, 54 into direct electrical communication with the resistor 24. It is to be recognized that the conductive regions 50 are openly exposed and oriented to be brought into operable electrical communication with the first and second wires 20, 22 and into direct electrical contact with the first and second conductive material layers 30, 32 upon slidably disposing the conductive regions 50 along axis 13 into the internal cavity 18.

The wire harness 26 can be provided as part of a self-contained wire harness assembly 56, including a quick connect conductive wire harness connector portion, referred to hereafter as wire harness connector portion 58, fixed directly to wires 60 of the wire harness 26. The wire harness connector portion 58 is configured to be readily disposed and fixed in the internal cavity 18 in operable electrical communication with the first wire 20 and the second wire 22. The wire harness connector portion 58 extends along the axis 13 in sandwiched relation between the first wire 20 and the second wire 22 in electrical communication therewith. In the example embodiment illustrated, the wire harness connector portion 58 is inserted into direct electrical contact with the first conductive material layer 30 and the second conductive material layer 32, such that the wire harness connector portion 58 extends along the axis 13 in sandwiched relation between the first conductive material layer 30 and the second conductive material layer 32. As shown, the wire harness connector portion 58 is simply inserted axially within the gap G in plug-like fashion to bring the wires 60 of wire harness 26 into electrical communication with the first and second wires 20, 22, thereby establishing an easy and reliable electrical connection between the first and second wires 20, 22 and the wire harness 26 without having to strip away material of the surrounding wall 28 of the sensor body 12. Then, to secure fixation of the wire harness assembly 56 to the sensor body 12, an end cap 49 can be disposed over at least a portion of the wire harness assembly 56, with the end cap 49 functioning to both secure attachment of the wire harness assembly 56 to the sensor body 12 and to protect the connection region of wire harness assembly 56 against exposure to contamination from the outside environment and other forms of damage. The end cap 49 can be formed of any suitable polymeric, dielectric material, such as in an over-molding operation, by way of example and without limitation. The end cap 49 may have a low profile shape, conforming substantially to the outer shape of the wire harness connector portion 58. Otherwise, the end cap 49 could be pre-formed and secured about the wire harness connector portion 58 and to the end 16 of the sensor body 12 via any suitable adhesive, press-fit, fastener, or otherwise.

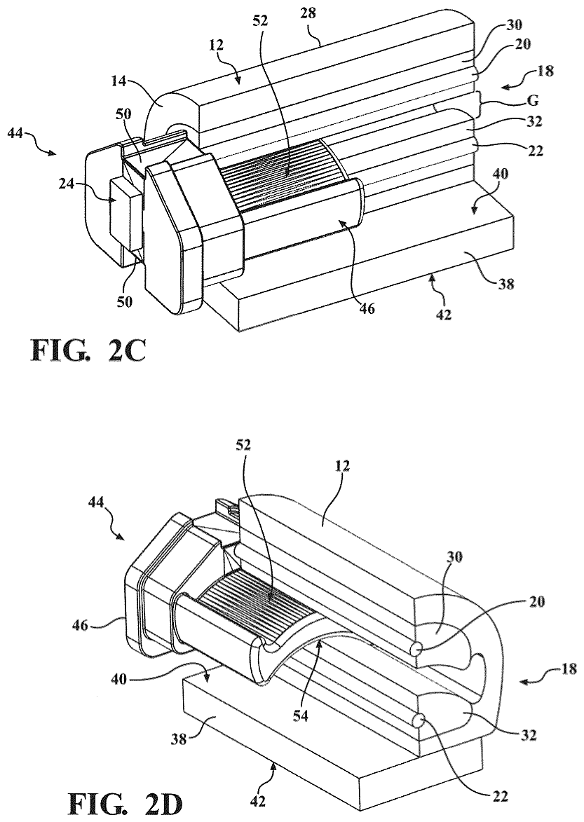

The wire harness connector portion 58, in order to provide electrical communication between the first and second wires 20, 22 and the wires 60 of wire harness 26, has wire harness conductive regions, referred to hereafter as connector regions 62, such as conductive metal strips or conductive layers of material, by way of example and without limitation, extending along respective opposite upper and lower outer surfaces 64, 66 of an insertable portion 61, shaped and sized for insertion into gap G, into direct electrical communication with the wires 60 by sliding receipt within cavity 18 illustrated by arrow S (FIG. 4A). It is to be recognized that the conductive regions 62 are oriented to be brought into operable electrical communication with the first and second wires 20, 22 and into direct electrical contact with the first and second conductive material layers 30, 32 upon slidably disposing the conductive regions 62 into the internal cavity 18. The wire harness connector portion 58 is shown in FIG. 3A, by way of example and without limitation, as having opposite halves configured for a clam shell like snap fit to one another, though other arrangements, including over-molding or otherwise, are contemplated herein.

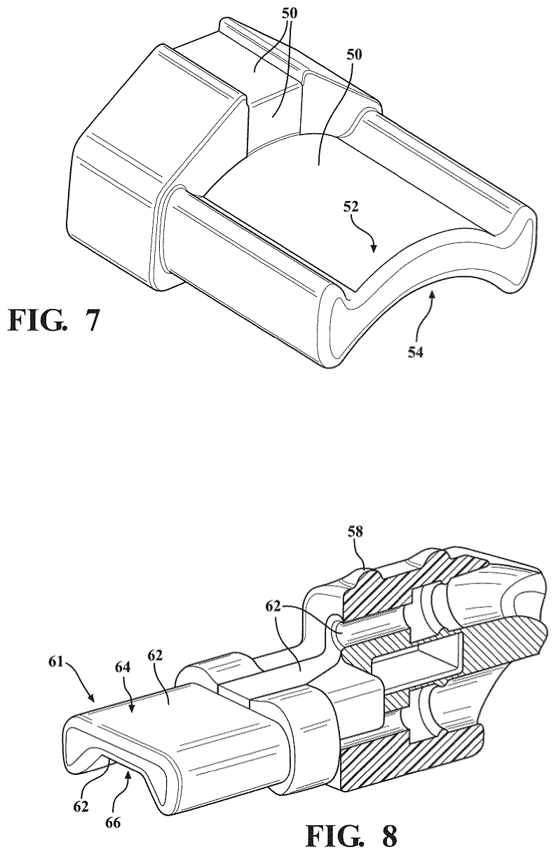

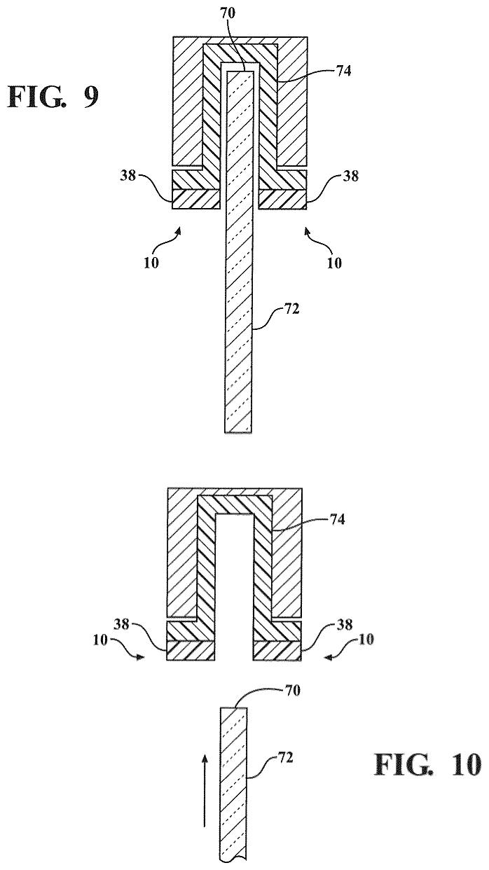

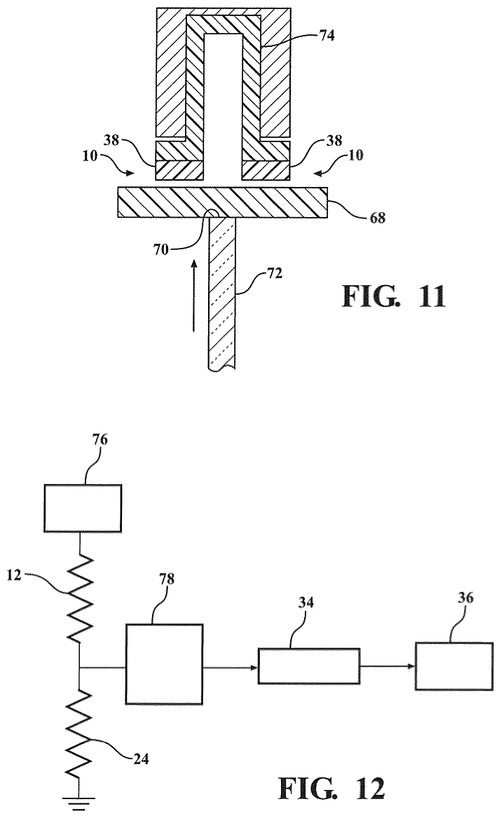

In FIGS. 9-11, a vehicle window application is shown, by way of example and without limitation, wherein a pair of contact sensors 10 constructed in accordance with the disclosure are used as pinch sensors to indicate when an object 68 comes between a leading edge 70 of a window 72 and the sensors 10. The sensors 10 are shown as being fixed to an upper door header 74 of the vehicle, such as via the backing member 38. In FIG. 9, the window 72 is shown in a fully closed, position, without any obstruction present. In FIG. 10, the window 72 is shown in a lowered position, and in FIG. 11 the window 72 is shown being raised from the lowered position of FIG. 10 toward the closed position of FIG. 9; however, the object 68 is shown disposed between the leading edge 70 of the window 72 and the upper door header 74. The object 68, upon impacting the sensor or sensors 10, causes the respective sensor 10 to be radially and resiliently compressed, and thus, as discussed above, the resistance of the sensor 10 is increased, thereby triggering an action to reverse the direction of travel of the window 72.

As shown schematically in FIG. 12, a constant voltage is applied to the contact sensor 10, such as via a low-dropout voltage regulator 76 having a maximum current output of about 20 mA and applying about 1.0 volts+/−1%, by way of example and without limitation. Further, a voltage controlled pulse width modulator (VCPWM) 78 may be disposed between the pinch strip or contact sensor 10 and the resistor 24, wherein the VCPWM 78 measures the voltage at the input and varies the output pulse width at a frequency of about 1 kHz, by way of example and without limitation. The voltage controlled pulse width modulator (VCPWM) may include a voltage controlled oscillator (VCO), as shown in FIG. 13. As the resistance of the pinch strip or contact sensor 10 varies, such by being increased under the application of the compression force to the sensor body 12 by the object 68, the pulse width output of the VCPWM 78 decreases, and the microcontroller 34, sometimes referred to as microprocessor or microcontrol unit, causes the window 72 to reverse direction via actuator 36 back toward an open position. The microcontroller 34 can be configured to sample the voltage input about every 10 ms, by way of example and without limitation, and if the resistance of the pinch strip contact sensor 10 is determined to have changed by more than about 5% from a baseline resistance, a pinch condition is detected, and the microcontroller 34 commands the actuator 36 to respond accordingly.

The baseline resistance can be set via a sampling monitored by the microcontroller 34, thereby allowing the microcontroller 34 to account for environmental conditions, such as ambient temperature, humidity and vibration, for example. With the above noted sampling being performed about every 10 ms, the microcontroller 34 can be configured to calculate an average of the pulse widths, such as between about every 1-5 minutes, by way of example and without limitation. Then, having calculated the baseline of an average of the pulse widths, the microcontroller 34, upon detecting a change in resistance of about 5%, will cause the aforementioned action to be taken by the actuator 36.

Accordingly, given the description above, in association with the various Figures, it is to be understood that various configurations of sensor bodies are possible, including elongate strips and planar or substantially planar sheets, which are contemplated to be within the scope of the invention. For example, in addition to the window application shown, many other applications, including by way of example and without limitation, planar and non-planar applications, such as vehicle seat occupant detection applications, interior/exterior trim applications, interior/exterior handle applications, and various closure member applications can benefit from the incorporation of a sensor having a variable resistance conductive sensor body constructed in accordance with the invention. It is to be further understood that applications requiring a sensor/switch to be activated in response to thermal conditions and/or human touch can also benefit from a sensor/sensor body constructed in accordance with the invention, as the variable resistance material of the sensor body can be monitored by the microcontroller for changes in response to thermal changes/touch, with the microcontroller being configured, such as via the aforementioned moving average algorithm of ambient temperature, to determine anticipated, normal changes in temperature, which would not initiate a command instruction from the microcontroller, versus changes in temperature due to human touch, which would initiate a command from the microcontroller.

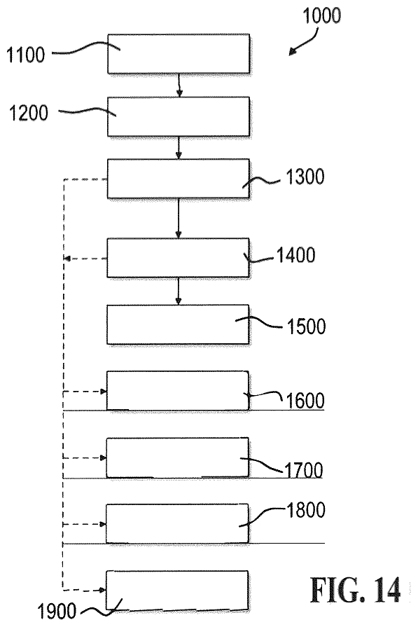

It is a related aspect of the present disclosure to provide a method of constructing a variable resistance contact sensor as discussed above and as shown diagrammatically at 1000 in FIG. 14. The method includes a step 1100 of providing a sensor body 12 having an internal cavity 18 extending between a first end 14 and an opposite second end 16, with a first wire 20 and a second wire 22 extending through the internal cavity 18 in spaced relation from one another and terminating in substantially flush relation with the first end 14 and the second end 16. Further, a step 1200 of providing a resistor assembly 44 having a resistor connector portion 46 and a resistor 24 fixed to the resistor connector portion 46. Then, at step 1300, inserting the resistor connector portion 46 into the internal cavity 18 of the sensor body 12 adjacent one of the first end 14 and second end 16 and bringing the resistor 24 into electrical communication with the first wire 20 and the second wire 22. Further, at step 1400, providing a wire harness assembly 56 having a wire harness connector portion 58 and a wire harness 26 including a plurality of wires, shown as a pair of wires 60, fixed to the wire harness connector portion 58. Then, at step 1500, inserting the wire harness connector portion 58 into the internal cavity 18 of the sensor body 12 adjacent an opposite one of the first end 14 and second end 16 from the resistor assembly 44 and bringing the plurality of wires 60 into electrical communication with the first wire 20 and the second wire 22.

In accordance with a further aspect, the method 1000 can include step 1600 of providing the resistor connector portion 46 having resistor conductive regions 50 in electrical communication with the resistor 24 and bringing the resistor conductive regions 50 into electrical communication with the first wire 20 and the second wire 22 automatically as a result of inserting the resistor connector portion 46 into the internal cavity 18 of the sensor body 12.

In accordance with a further aspect, the method 1000 can include step 1700 of providing the first wire 20 having a first conductive material layer 30 encapsulating the first wire 20 and the second wire 22 having a second conductive material layer 32 encapsulating the second wire 22 and bringing the resistor conductive regions 50 into direct electrical contact with the first conductive material layer 30 and second conductive material layer 32 automatically upon inserting the resistor connector portion 46 into the internal cavity 18 of the sensor body 12.

In accordance with a further aspect, the method 1000 can include step 1800 of providing the wire harness connector portion 58 having wire harness conductive regions 62 in electrical communication with the plurality of wires 60 and bringing the wire harness conductive regions 62 into electrical communication with the first wire 20 and the second wire 22 automatically upon inserting the wire harness connector portion 58 into the internal cavity 18 of the sensor body 12.

In accordance with a further aspect, the method 1000 can include step 1900 of providing the first wire 20, an example of a first conductor, having a first conductive material layer 30 encapsulating the first wire 20 and the second wire 22, an example of a second conductor, having a second conductive material layer 32 encapsulating the second wire 22 and bringing the wire harness conductive regions 62 into direct electrical contact with the first conductive material layer 30 and the second conductive material layer 32 automatically upon inserting the wire harness connector portion 58 into the internal cavity 18 of the sensor body 12.

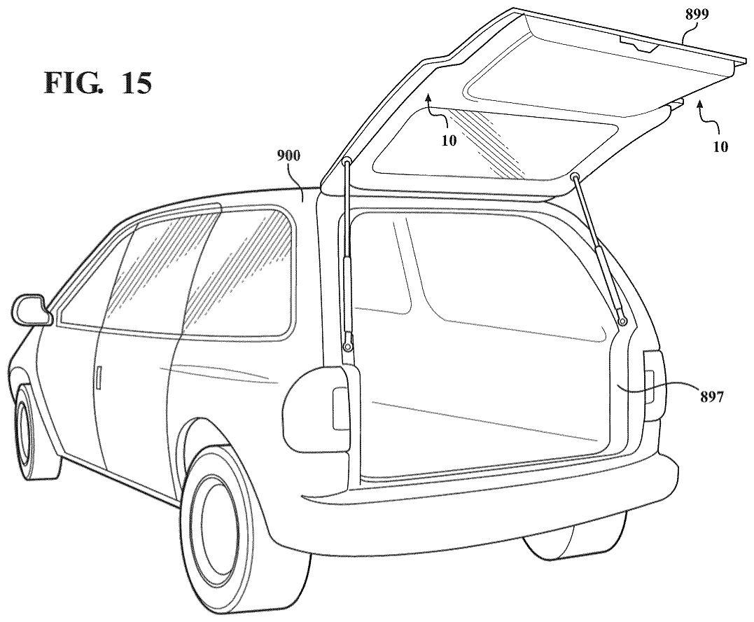

Now referring to FIG. 15, there is shown generally a motor vehicle 900 equipped with a contact sensor 10 as described herein, and in particular a closure panel 899 equipped with a contact sensor 10 along an inner periphery of the closure panel 899 as described herein, for illustratively providing anti-pinch detection functionality when closing the closure panel 899 against a vehicle body 897.

While the above description constitutes a plurality of embodiments of the present invention, it will be appreciated that the present invention is subject to further modification and change without departing from the fair interpretation and intended meaning of the accompanying claims.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A contact sensor, comprising:
a sensor body extending along an axis between a first end and an opposite second end, said sensor body having an internal cavity;
a first conductor extending through said internal cavity between said first end and said second end of said sensor body;
a second conductor extending through said internal cavity between said first end and said second end of said sensor body in spaced relation and out of electrical communication from said first conductor; and
a wire harness fixed in electrical communication with said first conductor and said second conductor adjacent at least one of said first end and said second end of said sensor body;
wherein said first conductor and said second conductor do not extend axially outwardly from said internal cavity beyond said at least one first end and said second end of said sensor body.

2. The contact sensor of claim 1, wherein the wire harness has an insertable portion inserted into the internal cavity.

3. The contact sensor of claim 1, wherein said first conductor is a first wire and second conductor is a said second wire.

4. The contact sensor of claim 3, further including a resistor fixed in electrical communication with said first wire and said second wire adjacent one of said first end and said second end of said sensor body.

5. The contact sensor of claim 4, further including a conductive resistor connector portion fixed in electrical communication with said resistor, said conductive resistor connector portion extending into said internal cavity in electrical communication with said first wire and said second wire in sandwiched relation between said first wire and said second wire, wherein said resistor is disposed outwardly from said internal cavity.

6. The contact sensor of claim 5, further including a first conductive material layer encapsulating said first wire and a second conductive material layer encapsulating said second wire, said first conductive material layer and said second conductive material layer being maintained out of direct physical contact with one another.

7. The contact sensor of claim 6, wherein said conductive resistor connector portion is in direct electrical contact with said first conductive material layer and said second conductive material layer.

8. The contact sensor of claim 4, further including a conductive wire harness connector portion fixed in electrical communication with said wire harness, said conductive wire harness connector portion extending into said internal cavity along said axis in sandwiched relation between said first wire and said second wire in electrical communication with said first wire and said second wire.

9. The contact sensor of claim 8, further including a first conductive material layer encapsulating said first wire and a second conductive material layer encapsulating said second wire, said first conductive material layer and said second conductive material layer being maintained out of direct physical contact with one another.

10. The contact sensor of claim 9, wherein said conductive wire harness portion is in direct electrical contact with said first conductive material layer and said second conductive material layer.

11. A contact sensor, comprising:
a sensor body extending along an axis between a first end and an opposite second end, said sensor body having an internal cavity;
a first conductor extending through said internal cavity between said first end and said second end of said sensor body;
a second conductor extending through said internal cavity between said first end and said second end of said sensor body in spaced relation and out of electrical communication from said first conductor;
a wire harness fixed in electrical communication with said first conductor and said second conductor adjacent at least one of said first end and said second end of said sensor body;
wherein said first conductor and said second conductor do not extend axially outwardly from said internal cavity beyond said at least one first end and said second end of said sensor body;
a resistor fixed in electrical communication with said first conductor and said second conductor adjacent one of said first end and said second end of said sensor body;
a conductive resistor connector portion fixed in electrical communication with said resistor, said conductive resistor connector portion extending into said internal cavity in electrical communication with said first conductor and said second conductor in sandwiched relation between said first conductor and said second conductor, wherein said resistor is disposed outwardly from said internal cavity; and
a conductive wire harness connector portion fixed in electrical communication with said wire harness, said conductive wire harness connector portion extending into said internal cavity along said axis in sandwiched relation between said first conductor and said second conductor in electrical communication with said first conductor and said second conductor.

12. The contact sensor of claim 11, further including a first conductive material layer encapsulating said first conductor and a second conductive material layer encapsulating said second conductor, said first conductive material layer and said second conductive material layer being maintained out of direct physical contact with one another.

13. The contact sensor of claim 12, wherein said conductive resistor connector portion is in direct electrical contact with said first conductive material layer and said second conductive material layer and wherein said conductive wire harness connector portion is in direct electrical contact with said first conductive material layer and said conductive material layer.
